(19) United States
(12) Patent Application Publication
(10) Pub. No.: US 2026/0051867 A1
(43) Pub. Date: Feb. 19, 2026

(54) SYSTEMS FOR SENSING AND MITIGATING VIBRATIONS USING AN ACOUSTIC RESONATOR

(71) Applicant: Toyota Motor Engineering & Manufacturing North America, Inc., Plano, TX (US)

(72) Inventors: Taehwa Lee, Ann Arbor, MI (US); Xiaopeng Li, Ann Arbor, MI (US); Ziqi Yu, Ann Arbor, MI (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 18/804,245

(22) Filed: Aug. 14, 2024

(51) Int. Cl. H03H 9/02; H03H 9/05

(52) U.S. Cl. CPC H03H 9/02086; H03H 9/0595

(57) ABSTRACT

Systems and other embodiments described herein relate to an acoustic resonator sensing or mitigating vibration waves associated with a structure having limited bonding. In one embodiment, the acoustic resonator includes a body having an interior channel from an open end to a closed end. The acoustic resonator can also include the body receiving an excitation by a vibration wave that propagates from a structure through the interior channel, the excitation occurring at a resonant frequency. The acoustic resonator can also include the body being proximate to the structure without physical bonding.

### TECHNICAL FIELD

The subject matter described herein relates, in general, to an acoustic resonator situated near a structure, and, more particularly, to the acoustic resonator sensing or mitigating vibration waves associated with the structure without physical bonding.

### BACKGROUND

Vibration waves in materials and structures can originate from various sources. In a vehicle environment, for example, a mechanical load and dynamic forces from components generate vibration waves. Temperature changes causing thermal expansion and contraction, fluid flow turbulence, and operational processes like drilling can also generate vibration waves in various environments. Identifying and reducing vibration waves can increase material integrity and performance.

In various implementations, vibration waves in materials cause failure and degradation without sensing and mitigation. For instance, external vibration waves matching the natural frequency of a material as resonance amplifies oscillations that damage structures such as bridges and buildings and increase collapse risk. Additionally, vibrations can contribute to noise and vibration pollution, affecting both machinery performance and environmental quality. Furthermore, intense vibration waves can cause micro-cracking and weaken a material over time. Vibration waves can also interfere with precision equipment that disrupts accuracy and generates unwanted heat causing thermal damage. Accordingly, vibration waves originate from various sources and exhibit detrimental effects to materials when unaddressed, such as from resonant noise and thermal degradation.

### SUMMARY

In one embodiment, example systems relate to an acoustic resonator sensing or mitigating vibration waves associated with a structure having limited bonding. In various implementations, systems attenuate vibration waves caused by structural turbulence, thermal variance, etc., using mechanical resonators attached to a material. Attaching through bonding a mechanical resonator can increase manufacturing costs. Furthermore, coupling a resonator with a material for sensing or attenuation can be infeasible from assembly constraints and packaging sizes.

Therefore, in one embodiment, an acoustic resonator senses or mitigates a vibration wave (e.g., an acoustic wave) from a structure at a distance without involving bonding, thereby avoiding additional system complexities. In one approach, the acoustic resonator is positioned close to a plate without actual contact, thereby simplifying manufacturing and reducing costs over mechanical resonators. This also allows installing the acoustic resonator in diverse environments since physical contact with a target medium for sensing and mitigation is unnecessary, thereby improving system robustness.

The acoustic resonator can operator in diverse environments for sensing or mitigating the vibration wave. For example, the acoustic resonator is a rigid material installed on a vehicle frame. A vehicle scenario can involve motion causing a door panel near the acoustic resonator to generate a vibration wave from shaking. Here, the vibration wave travels from the door panel towards the acoustic resonator. Traveling through the acoustic resonator causes an excitation at a resonant frequency. For instance, the resonant frequency is inversely proportional to a length of the acoustic resonator. As such, the acoustic resonator can sense the vibration wave through measurements of a transducer (e.g., a microphone). Furthermore, the acoustic resonator can mitigate the vibration wave through an interior space having dimensions and materials purpose-built for absorption at frequencies corresponding with the vibration wave. Thus, the acoustic resonator improves sensing and interference mitigation of a vibration through contactless configurations that increase applications while reducing costs.

In one embodiment, an acoustic resonator sensing or mitigating vibration waves associated with a structure having limited bonding is disclosed. The acoustic resonator can include a body having an interior channel from an open end to a closed end. The acoustic resonator can also include the body receiving an excitation by a vibration wave that propagates from a structure through the interior channel, the excitation occurring at a resonant frequency. The acoustic resonator can also include the body positioned proximate to the structure without physical bonding.

### BRIEF DESCRIPTION OF THE DRAWINGS

The accompanying drawings, which are incorporated in and constitute a part of the specification, illustrate various systems and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of an acoustic resonator positioned near a plate having a vibration wave.

FIGS. 2A-2C illustrate embodiments of the acoustic resonator having various widths for sensing and mitigating the vibration wave.

FIG. 3 illustrates an example of reflection and absorption spectra of the acoustic resonator and the vibration wave.

FIG. 4 illustrates an example of reflection, transmission, and absorption spectra for a structure including a two-port setup involving the acoustic resonator and the vibration wave.

### DETAILED DESCRIPTION

Systems and other embodiments associated with an acoustic resonator that senses or mitigates a vibration wave from a structure having limited bonding with a target source are disclosed herein. In various implementations, sensing and attenuating vibration waves using mechanical resonators (e.g., piezoelectric resonators) attached to structures (e.g., a plate) is an effective technique for controlling vibrations. However, mechanical resonators often involve bonding and physically fixing to the material for these applications, which can increase the overall manufacturing complexity. Additionally, integrating a resonator with a material for purposes like sensing or vibration attenuation can be challenging from limitations in assembly processes and form factor specifications that are constraining.

Therefore, in one embodiment, an acoustic resonator operates having limited bonding with a structure for sensing or reducing a vibration wave (e.g., an acoustic wave) generated by a structure (e.g., a plate). For a sensing setup, in one approach, the acoustic resonator is a rigid plastic within a packaged sensor that monitors the vibration wave using a transducer line, such as within a vehicle environment. For example, the transducer line (e.g., a microphone) is inside the acoustic resonator and signals the measurements for downstream tasks (e.g., an alarm, speed control, etc.). Here, the acoustic resonator can have a body with an interior space (e.g., a cavity, a channel, etc.) receiving a vibration wave that propagates from the structure through the interior space. An excitation can occur at a resonant frequency for sensing by the body positioned near the structure without bonding (e.g., direct bonding, physical bonding, intermediate bonding, etc.). The resonant frequency can be inversely proportional to the length of the body and a bandwidth is proportional to a width of the body. For instance, the body senses the vibration wave through measuring the resonant excitation using a transducer line. As such, varying the body length and width allows acoustic sensing of different vibration frequencies.

In various implementations, a setup mitigating a vibration wave involves having a body with an increased width and decreased reflection for absorbing the vibration wave, such as through thermoviscous dissipation while traveling through the interior space. Here, the increased width is directly proportional with a bandwidth associated with the resonant frequency. Furthermore, the body can include foam that increases absorption and reduces reflection of the vibration wave while being a distance from the structure. This allows purpose building the acoustic resonator to mitigate vibration waves exhibiting different frequencies through having various widths and materials. Accordingly, a system including the acoustic resonator improves sensing and interference mitigation of a vibration wave without physical contact and bonding that reduces costs and expands applications.

In the following examples, it will be appreciated that for simplicity and clarity of illustration, where appropriate, reference numerals have been repeated among the different figures to indicate corresponding or analogous elements. In addition, the discussion outlines numerous specific details to provide a thorough understanding of the embodiments described herein. Those of skill in the art, however, will understand that the embodiments described herein may be practiced using various combinations of these elements.

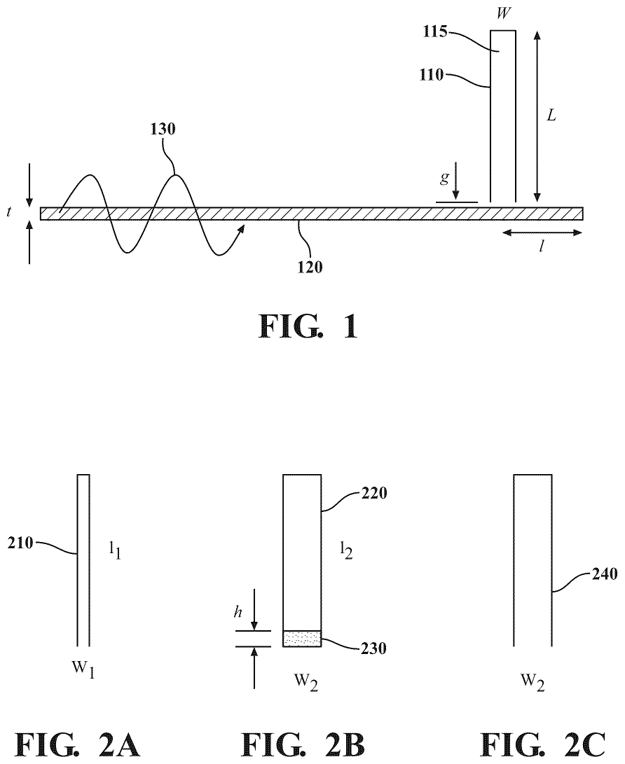

Turning now to FIG. 1, one embodiment of an acoustic resonator 110 positioned near a structure 120 having a vibration wave 130 is illustrated. In one approach, the structure 120 is one of a plate, a beam, and a panel associated with a device (e.g., a vehicle) having a thickness t and a limited length. As previously explained, the acoustic resonator can be a rigid material installed on a vehicle frame near a door panel. A driving scenario can involve encountering a road hazard (e.g., a pothole) causing the door panel to generate a vibration wave from shaking. The vibration wave travels a length of the door panel and through the acoustic resonator causing unintended cabin noise, structural degradation, etc. Although examples given herein reference vehicle environments, the acoustic resonator 110 can sense and mitigate the vibration wave in diverse environments.

The acoustic resonator 110 can be positioned near the end of the structure 120 and excited by the vibration wave 130 (e.g., an acoustic wave) propagating through the structure 120. In another approach, the acoustic resonator 110 is positioned a distance/from the end of the structure 120 for optimizing vibration detection through enhancing resonance peaks from absorption and reflectance associated with the vibration wave 130. For instance, the acoustic resonator 110 is proximate to the end of the structure 120 for observing peak energy levels associated with the vibration wave 130. In once approach, the body is one of a rigid metal, rigid aluminum, a metal cylinder, a metal pipe, a plastic cylinder, and a plastic pipe, thereby exhibiting decreased costs and easier installation. In a vehicle environment, the acoustic resonator 110 has a body that can be attached on a frame of the vehicle, and comprises a limited length.

In various implementations, the acoustic resonator 110 detects the vibration wave 130 lacking bonding or adhesion with the structure 120. As such, the acoustic resonator 110 can be contactless with the structure 120. Although this example describes the acoustic resonator 110 detecting the vibration wave 130, other examples forthcoming include mitigating and absorbing the vibration wave 130 for reducing noise and interference. Bonding can include physical bonding, direct bonding, intermediate bonding, etc., that impacts how the acoustic resonator 110 receives the vibration wave 130. Physical bonding can be connecting with a material (e.g., adhesive) having a limited size for a bond. Direct bonding can be the acoustic resonator 110 and the structure 120 being in contact without having an intermediate component. Indirect bonding can be the acoustic resonator 110 and the structure 120 having indirect contact through one or more other structures.

Moreover, the frequency response of the acoustic resonator 110 reaches a maximum value through resonance when the frequency of the vibration wave 130 matches with that of the acoustic resonator 110. The resonance frequency of the acoustic resonator 110 can be given by f=c/2L, where c is the sound of speed. The gap g (e.g., less than 1 millimeter (mm)) can be an empty space between the acoustic resonator 110 and the structure 120. As further explained below, a bandwidth for sensing or mitigation involving the vibration wave 130 can be proportional to a body width W of the acoustic resonator 110. Furthermore, in another approach, the acoustic resonator 110 exhibits improved performance while simplifying implementation by touching the structure 120 without bonding and exhibiting contact with the structure 120 without using one of a glue and an adhesive. The structure 120 and the acoustic resonator 110 can also have a glue within the gap g that allows loose contact, limited contact, foam (e.g., acoustic foam), etc., without bonding for optimizing operation for certain scenarios and materials.

In one approach, the acoustic resonator 110 includes a body having an open end and a closed end. Here, the body can have the channel 115 (e.g., an interior channel) extending from the open end to the closed end. The channel 115 can also be between the open end and the closed end of the body such that the gap g exists at the open end. As such, the body can be positioned proximate to the structure 120 without physical bonding and contactless from the structure 120. Furthermore, the body can experience an excitation at a resonant frequency by the vibration wave 130 propagating from the structure 120 through the channel 115. The excitation can be caused by the vibration wave 130 losing energy from thermoviscous dissipation while traveling through the channel 115. As in other examples, the body can be positioned proximate to the structure 120 without physical bonding, thereby simplifying installations. Regarding sensing, the acoustic resonator 110 senses the vibration wave 130 through measurements of a transducer (e.g., a microphone). For instance, systems downstream from the acoustic resonator 110 can receive signals including measurements from the transducer for tasks (e.g., an alarm, speed control, etc.).

In one embodiment, the acoustic resonator 110 includes a body having an open end and a closed end such that a cavity forms the channel 115 from the open end to the closed end. Here, the body can experience an excitation at a resonant frequency by the vibration wave 130 propagating and traveling from the structure 120 through an air medium to the channel 115. A frequency response of the excitation can exhibit a bandwidth directly proportional to the width W. In one approach, the body is positioned proximate to an end of the structure 120 with physical bonding that is limited. For instance, the body has limited contact with the structure 120 and the physical bonding comprises one of an adhesive and acoustic foam. In this way, the acoustic resonator 110 optimizes sensing or interference mitigation involving applications demanding bonding for certain materials.

Now discussing FIGS. 2A-2C, embodiments of acoustic resonators having various widths for sensing and mitigating a vibration wave lacking a bond with the structure 120 are illustrated. Here, a frequency response of the excitation for acoustic resonators can exhibit a bandwidth directly proportional to widths W₁ and W₂. The acoustic resonators are purpose-built with different widths allowing applications demanding varying bandwidths associated with different vibration waves. For example, the acoustic resonator 210 and the acoustic resonator 220 have comparable peak values at resonance frequencies for detecting the vibration wave 130 when lengths l₁ and l₂ are similar. The resonance frequency can be f=c/2L, where L is l₁ or l₂. However, the acoustic resonator 220 exhibits a wider bandwidth for sensing or mitigating broad frequencies as the bandwidth is directly proportional to W₂, and W₂ is greater than W₁. Thus, systems can include variations of the acoustic resonator 110 that is purpose-built through varying length and width.

Moreover, the acoustic resonator 210 can have a limited width W₁ while exhibiting loss from thermoviscous dissipation within the acoustic resonator 210. Furthermore, the acoustic resonator 220 has an expanded width W₂ and exhibits lossiness with the foam 230 for damping. In one approach, the foam 230 is one of a solid foam, a porous foam, an acoustic foam, and a vibration absorbing material having a height h. Lossiness involving the acoustic resonator 210 and the acoustic resonator 220 can be beneficial for applications involving mitigating and attenuating the vibration wave 130. For instance, the acoustic resonator 210 has a narrow channel and an open end such that the vibration wave 130 loses energy and dissipates while traveling through the narrow channel. In another example, the body having an increased width W₂ mitigates the vibration wave 130 using absorption through an expanded bandwidth, thereby reducing interference and system damage from material degradation. Meanwhile, the acoustic resonator 240 has an expanded width W₂ that exhibits limited loss without the foam 230 when demanded by certain sensing and mitigation applications for vibration waves. In some configurations, lacking the foam 230 can reduce manufacturing and materials costs of the acoustic resonator 210.

Regarding another example involving mitigating the vibration wave 130, the body of the acoustic resonator 220 can have the foam 230 that is solid at one of an open end and a closed end as the vibration wave 130 travels through and among the acoustic resonator 220. Here, the body has an increased width W₂ that mitigates the vibration wave 130 using absorption from the foam 230 or another material that absorbs vibrations, vibration energy, etc. As previously explained, the increased width W₂ is directly proportional with the bandwidth associated with the resonant frequency. In this way, the acoustic resonator 220 exhibits broad bandwidth at a resonant frequency for absorbing various frequencies involving the vibration wave 130.

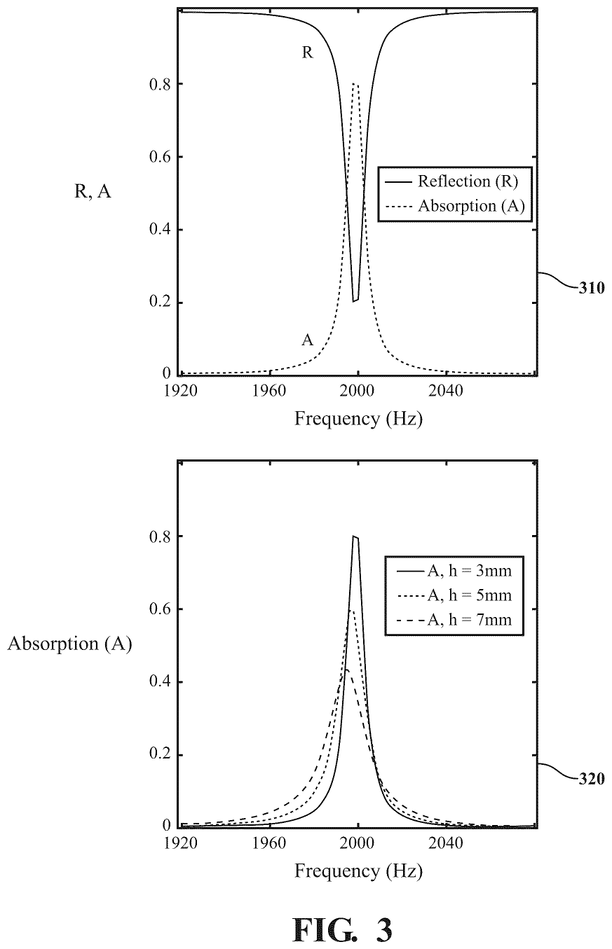

FIG. 3 illustrates an example of the reflection and absorption spectra involving an acoustic resonator having one port and a finite length and a vibration wave. In one embodiment, the acoustic resonator 110 has a W=20 mm and L=85.75 mm. For sensing applications, observing resonance can involve measuring one of an absorption peak and a reflection peak of a vibration wave using the acoustic resonator 110.

Regarding vibration mitigation, in one approach, the acoustic resonator 110 has foam with a h=3 mm and placed near the structure 120 that is an aluminum plate having a thickness of t=2 mm. Here, the acoustic resonator 110 can be located at l=30 mm from the end of the aluminum plate. For this setup, the reflection (R) and absorption (A) chart 310 indicates elevated absorption of approximately 80% at 2000 Hz through having limited reflectance. The chart 320 exhibits that absorption decreases while bandwidth increases at approximately 2000 Hz when foam thickness h increases. As such, the acoustic resonator 110 can adapt to expected properties such as frequency and peak levels of a vibration wave through changing foam thickness without bonding and while maintaining other parameters (e.g., width, length, etc.).

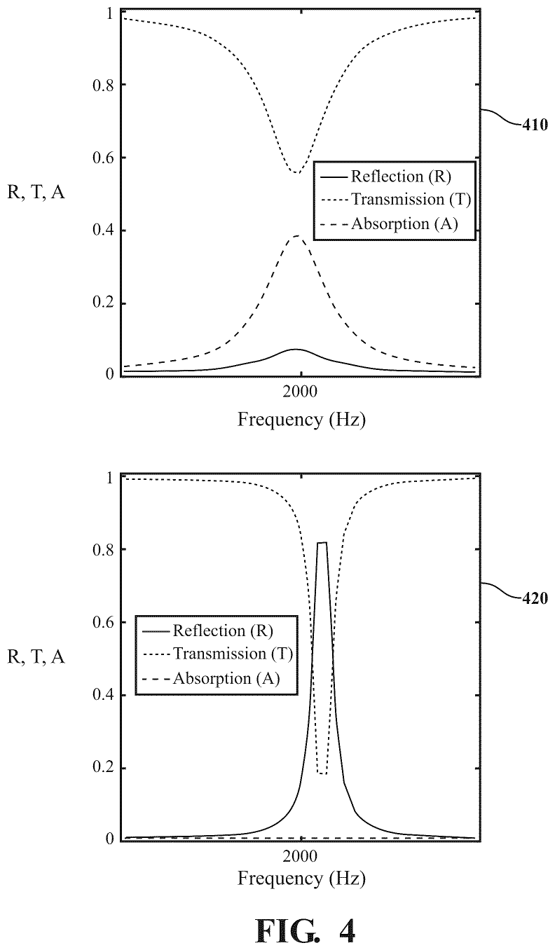

Regarding FIG. 4, an example of reflection, transmission, and absorption spectra for a structure (e.g., a plate) including a two-port setup with an acoustic resonator is illustrated. For sensing applications, observing resonance can involve measuring one of an absorption peak, a reflection peak, and a transmission dip of a vibration wave using the acoustic resonator 110. For vibration mitigation, the chart 410 shows reflection, transmission (T), and absorption spectra for the acoustic resonator 110 placed near a structure (e.g., a plate) that is infinitely long. As such, the vibration wave avoids reflection from a boundary at a structural endpoint, thereby improving vibration mitigation through absorption. In chart 410, absorption at 2000 Hz is approximately 40% while having an expanded bandwidth. Furthermore, the setup has low transmission from having elevated absorption and reflection even when including the foam 230. In the chart 420, the acoustic resonator is lossless and exhibits an elevated reflection peak in setups without the foam 230. Accordingly, the systems having various configurations for the acoustic resonator 110 exhibit improved performance with sensing and mitigating a vibration wave without bonding that reduces costs for diverse applications.

Detailed embodiments are disclosed herein. However, it is to be understood that the disclosed embodiments are intended as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Furthermore, the terms and phrases used herein are not intended to be limiting but rather to provide an understandable description of possible implementations. Various embodiments are shown in FIGS. 1-4 but the embodiments are not limited to the illustrated structure or application.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all combinations of one or more of the associated listed items. As an example, the phrase “at least one of A, B, and C” includes A, B, C, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. An acoustic resonator comprising:
a body having an interior channel from an open end to a closed end;
the body receiving an excitation by a vibration wave that propagates from a structure through the interior channel, the excitation occurring at a resonant frequency; and
the body proximate to the structure without physical bonding.

2. The acoustic resonator of claim 1, wherein the body senses the vibration wave with measuring the excitation at the resonant frequency using a transducer, and a bandwidth for sensing the vibration wave is proportional to a width of the body.

3. The acoustic resonator of claim 1 further comprising:
the body having foam at the open end; and
the body has an increased width that mitigates the vibration wave using absorption and the increased width is directly proportional with a bandwidth associated with the resonant frequency.

4. The acoustic resonator claim 3, wherein the vibration wave losses energy from thermoviscous dissipation while traveling through the interior channel.

5. The acoustic resonator of claim 1, wherein the body lacks contact with the structure.

6. The acoustic resonator of claim 1, wherein the body has contact with the structure without one of a glue and an adhesive.

7. The acoustic resonator of claim 1, wherein the structure is one of a plate and a beam having a limited length and the resonant frequency is inversely proportional to a length of the body.

8. The acoustic resonator of claim 1, wherein the structure is a door panel associated with a vehicle, the body is attached on a frame of the vehicle, and the structure has a limited length.

9. The acoustic resonator of claim 1, wherein the body is one of a rigid metal, rigid aluminum, a metal cylinder, a metal pipe, a plastic cylinder, and a plastic pipe.

10. An acoustic resonator comprising:
a body having an open end and a closed end;
the body having a channel from the open end to the closed end;
the body having an excitation by a vibration wave that propagates from a structure through the channel, the excitation occurring within a bandwidth and at a resonant frequency; and
the body positioned proximate to an end of the structure with physical bonding that is limited.

11. The acoustic resonator of claim 10, wherein the body senses the vibration wave with the excitation at the resonant frequency, and the bandwidth for sensing the vibration wave is proportional to a width of the body.

12. The acoustic resonator of claim 10 further comprising:
the body having acoustic foam at one of the open end and the closed end; and
the body has an increased width that mitigates the vibration wave using absorption and the increased width enlarges the bandwidth associated with the resonant frequency.

13. The acoustic resonator claim 11, wherein the vibration wave losses energy from thermoviscous dissipation while traveling through the channel.

14. The acoustic resonator of claim 10, wherein the body has limited contact with the structure and the physical bonding comprises one of an adhesive and acoustic foam.

15. The acoustic resonator of claim 10, wherein the structure is one of a plate and a beam having a limited length and the resonant frequency is inversely proportional to a length of the body.

16. The acoustic resonator of claim 10, wherein the structure is a door panel associated with a vehicle having a limited length and the body is positioned on a frame of the vehicle.

17. The acoustic resonator of claim 10, wherein the body is one of a rigid metal, rigid aluminum, a metal cylinder, a metal pipe, a plastic cylinder, and a plastic pipe.

18. A resonator comprising:
a body having a cavity between an open end and a closed end;
the body receiving an excitation by a vibration wave that is acoustic and propagates from a structure through the cavity that forms a channel, the excitation occurring at a resonant frequency and within a bandwidth; and
the body positioned proximate to the structure without physical bonding and contactless with the structure, the body having a gap between the open end and the structure.

19. The resonator of claim 18, wherein the body senses the vibration wave with the excitation at the resonant frequency using a transducer, and the bandwidth for sensing the vibration wave is proportional to a width of the body.

20. The resonator of claim 18 further comprising:
the body having acoustic foam that is one of a solid and a porous material at the open end; and
the body has an increased width that mitigates the vibration wave using absorption from the acoustic foam and the increased width is directly proportional with the bandwidth associated with the resonant frequency.
